(19) United States
(12) Patent Application Publication
(10) Pub. No.: US 2024/0030382 A1
(43) Pub. Date: Jan. 25, 2024

(54) DONOR SUBSTRATE AND LED TRANSFER METHOD USING SAME

(71) Applicant: LG Display Co., Ltd., Seoul (KR)

(72) Inventors: Chung Hwan AN, Goyang-si (KR); Do Jin KIM, Seoul (KR)

(73) Assignee: LG Display Co., Ltd., Seoul (KR)

(21) Appl. No.: 17/768,331

(22) PCT Filed: Mar. 12, 2020
(86) PCT No.: PCT/KR2020/003430

§ 371 Date: Apr. 12, 2022

(30) Foreign Application Priority Data
Oct. 29, 2019 (KR) 10-2019-0135785

(51) Int. Cl. H01L 33/20; H01L 25/075; H01L 23/544

(52) U.S. Cl. CPC H01L 33/20; H01L 25/0753; H01L 23/544; H01L 2223/54426

(57) ABSTRACT

A donor substrate according to an exemplary embodiment of the present disclosure comprises a base substrate, a resin layer disposed on one surface of the base substrate, a plurality of first protrusions disposed on the resin layer, and an alignment mark disposed on the base substrate. Therefore, as the alignment mark is disposed on the surface of the base substrate, it is possible to reduce a change in position of the alignment mark caused by the resin layer.

### TECHNICAL FIELD

The present disclosure relates to a display device, and more particularly, to a donor substrate having improved alignment accuracy and an LED transfer method using the same.

### BACKGROUND ART

Display devices used in computer monitors, TVs, and mobile phones include organic light emitting displays (OLEDs) that emit light by themselves, and liquid crystal displays (LCDs) that require a separate light source.

Such display devices are being applied to more and more various fields including not only computer monitors and TVs, but also personal mobile devices, and thus, display devices having a reduced volume and weight while having a wide display area are being studied.

In recent years, display devices including light emitting diodes (LEDs) have received attention as next-generation display devices. Since the LED is formed of an inorganic material rather than an organic material, it has excellent reliability and has a longer lifespan compared to a liquid crystal display or an organic light emitting display. In addition, the LED has a high lighting speed, high luminous efficiency and excellent stability due to high impact resistance and can display a high-brightness image.

### DISCLOSURE

### Technical Problem

In order to manufacture a display device including an LED, a process of transferring an LED which is manufactured on a wafer to a donor substrate and then, transferring the LED transferred to the donor substrate to a substrate of the display device is used.

Specifically, in a primary transfer process of transferring a plurality of LEDs of a wafer to the donor substrate, after aligning and bonding the wafer and the donor substrate, the plurality of LEDs may be transferred to the donor substrate. In a secondary transfer process of transferring the plurality of LEDs from the donor substrate to a display panel, after the display panel and the donor substrate are aligned and bonded, the plurality of LEDs are transferred to the display panel to thereby complete formation of the display device.

At this time, in order to align the donor substrate and the wafer, and the donor substrate and the display panel, alignment protrusions are formed using the same material and the same process as a plurality of protrusions to which the plurality of LEDs are temporarily attached, on the donor substrate and based on the alignment protrusions, it is possible to align the donor substrate and the wafer, and the donor substrate and the display panel. However, the inventors of the present disclosure have recognized that since the donor substrate is continuously used in the primary transfer process and the secondary transfer process, an alignment key may be damaged or the position thereof may be deformed due to an external impact and friction during a processing process.

In addition, the plurality of protrusions and alignment protrusions used in the donor substrate may be formed of a polymer having high transmittance and viscoelasticity such as polydimethylsiloxane (PDMS). For example, when the alignment protrusion is formed of PDMS, since the alignment protrusion is formed by coating and curing the PDMS, an edge of the alignment protrusion is not clearly formed, and may be rounded and unclearly formed. Therefore, the inventors of the present disclosure have recognized a defect that, due to the characteristics of the alignment protrusion, the edge of the alignment protrusion is somewhat unclear, and it is difficult to identify the alignment protrusion because it is confused with surrounding stains. In addition, when the identification of the alignment protrusion is delayed in process equipment, a process time is increased due to this, and a subsequent process is also delayed, thereby causing non-uniform distribution of the overall process time.

Accordingly, the inventors of the present disclosure have invented a donor substrate having a clear contrast ratio and alignment marks with minimal damage and positional deformation.

An object to be achieved by the present disclosure is to provide a donor substrate in which alignment marks can be easily identified by improving a contrast ratio between the alignment marks of the donor substrate and remaining components of the donor substrate.

Another object to be achieved by the present disclosure is to provide a donor substrate including alignment marks in which damage due to repeated use of the donor substrate and an external impact is reduced.

Another object to be solved by the present disclosure is to provide a donor substrate including alignment marks that reduce positional deformation due to stretching of a resin layer of the donor substrate.

Another object to be solved by the present disclosure is to provide a donor substrate capable of reducing a process time during LED transfer by easy identification of alignment marks.

Objects of the present disclosure are not limited to the above-mentioned objects, and other objects, which are not mentioned above, can be clearly understood by those skilled in the art from the following descriptions.

### Technical Solution

A donor substrate according to an exemplary embodiment of the present disclosure comprises a base substrate, a resin layer disposed on one surface of the base substrate, a plurality of first protrusions disposed on the resin layer; and an alignment mark disposed on the base substrate. Accordingly, by disposing the alignment mark on the surface of the base substrate, it is possible to reduce a change in position of the alignment mark due to the resin layer.

A donor substrate and a light emitting diode (LED) transfer method using the same according to another exemplary embodiment of the present disclosure comprises aligning a wafer and a donor substrate, and transferring a plurality of LEDs on the wafer to the donor substrate. And the donor substrate includes a base substrate on which an alignment mark is marked, a resin layer on the base substrate, and a plurality of first protrusions protruding from the resin layer, and the aligning of the wafer and the donor substrate is aligning the alignment mark of the donor substrate with an alignment key of the wafer. Therefore, since the donor substrate formed of the base substrate on which the alignment mark is displayed is used, the alignment mark can be easily identified during LED transfer and process delay can be reduced.

Other matters of the exemplary embodiments are included in the detailed description and the drawings.

### Advantageous Effects

According to the present disclosure, a contrast ratio between an alignment mark and a substrate and a resin layer in a donor substrate increases, so that the alignment mark can be easily identified.

According to the present disclosure, the alignment mark is formed directly on the substrate of the donor substrate, thereby reducing movement of the alignment mark due to stretching of the resin layer.

According to the present disclosure, it is possible to reduce damage to the alignment mark due to repeated use of the donor substrate or an external impact.

According to the present disclosure, it is easy to identify the alignment mark of the donor substrate, and thus process delay due to non-identification of the alignment mark can be reduced.

The effects according to the present disclosure are not limited to the contents exemplified above, and more various effects are included in the present specification.

### DESCRIPTION OF DRAWINGS

FIG. 1 is a plan view of a donor substrate according to an exemplary embodiment of the present disclosure.

FIG. 2A is a cross-sectional view taken along IIa-IIa′ of FIG. 1.

FIG. 2B is a cross-sectional view taken along IIb-IIb′ of FIG. 1.

FIGS. 3 and 4 are process flowcharts for explaining the donor substrate and an LED transfer method using the donor substrate according to an exemplary embodiment of the present disclosure.

FIGS. 5 and 6 are schematic process views for explaining the LED transfer method according to an exemplary embodiment of the present disclosure.

FIGS. 7A to 7C are enlarged plan views of a donor substrate according to a comparative example.

FIG. 8 is an enlarged rear view of a donor substrate according to another exemplary embodiment of the present disclosure.

FIG. 9 is a cross-sectional view of a donor substrate according to still another exemplary embodiment of the present disclosure.

### MODES OF THE DISCLOSURE

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a donor substrate and a LED transfer method using the same according to exemplary embodiments of the present disclosure will be described in detail with reference to accompanying drawings.

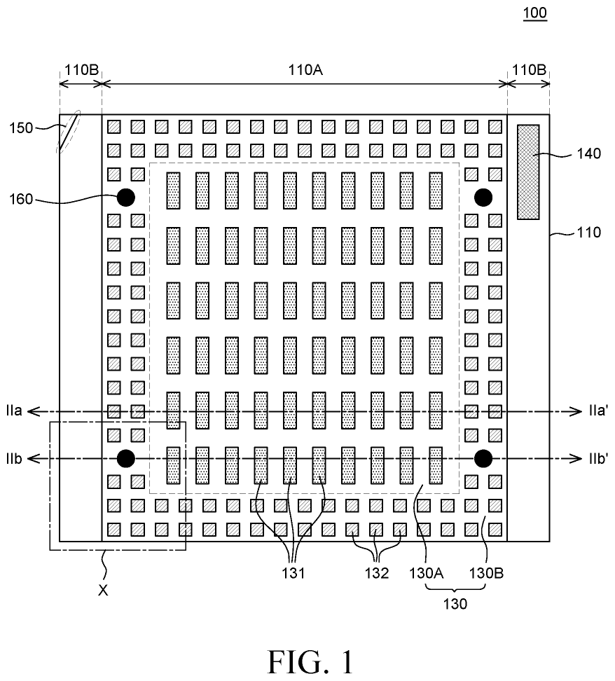

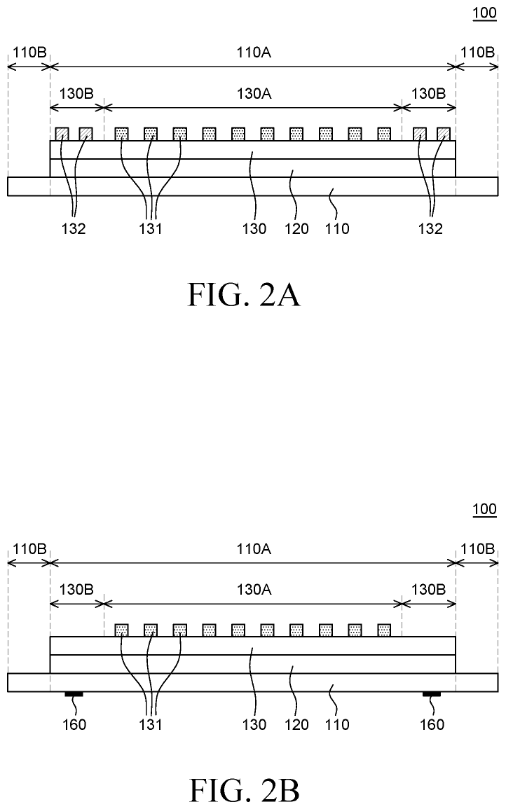

FIG. 1 is a plan view of a donor substrate according to an exemplary embodiment of the present disclosure. FIG. 2A is a cross-sectional view taken along IIb-IIb′ of FIG. 1. FIG. 2B is a cross-sectional view taken along IIb-IIb′ of FIG. 1. Referring to FIGS. 1 to 2B, a donor substrate 100 according to an exemplary embodiment of the present disclosure includes a substrate 110, an adhesive layer 120, a resin layer 130, a plurality of first protrusions 131, a plurality of second protrusions 132 and alignment marks 160.

The substrate 110 is configured to support various components included in the donor substrate 100, and may be formed of a material which is more rigid than the resin layer 130 in order to reduce warpage of the resin layer 130. For example, the substrate 110 may be formed to include a polymer or plastic, and may be formed of PC (poly carbonate) or PET (poly ethylene terephthalate), but is not limited thereto.

The substrate 110 includes a transfer region 110A and non-transfer regions 110B.

The transfer region 110A is a region overlapping the resin layer 130. The transfer region 110A is disposed to overlap the resin layer 130, the plurality of first protrusions 131, and the plurality of second protrusions 132, and may support the resin layer 130, the plurality of first protrusions 131, and the plurality of second protrusions 132. The transfer region 110A is a region to which a plurality of LEDs are temporarily transferred, and may be disposed to overlap at least a portion of a wafer or a display panel during a transfer process.

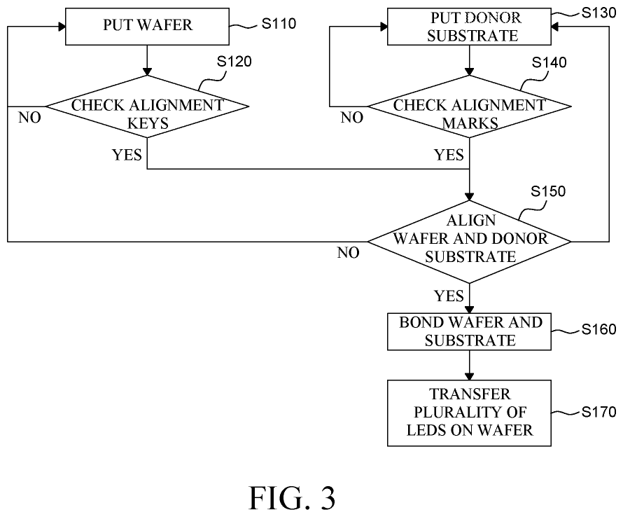

Meanwhile, the wafer is a substrate on which a plurality of LEDs are formed. The plurality of LEDs formed on the wafer are primarily transferred to the donor substrate 100, and the plurality of LEDs on the donor substrate 100 are secondarily transferred to the substrate 110, so that a display panel may be formed. This will be described later in detail with reference to FIGS. 3 to 6.

The non-transfer region 110B is a region protruding to an outside of the resin layer 130. The non-transfer region 110B is a region that does not overlap the resin layer 130. The non-transfer region 110B is a region in which the plurality of LEDs are not disposed. An identification pattern 140 and a direction pattern 150, instead of the plurality of LEDs may be disposed in the non-transfer region 110B.

The identification pattern 140 is a pattern formed in the non-transfer region 110B to identify the donor substrate 100. A plurality of donor substrates 100 may be managed by using a unique identification pattern 140 provided to each donor substrate 100. The identification pattern 140 may be disposed on an upper surface or a back surface of the substrate 110, and may be formed by a printing method or a laser engraving method. For example, the identification pattern 140 may be an ID or barcode which is composed of numbers or characters, but is not limited thereto. Meanwhile, although the identification pattern 140 is illustrated as being formed on an upper right side of the donor substrate 100 in FIG. 1, the identification pattern 140 may be variously disposed in the non-transfer region 110B, and the number and arrangement of the identification pattern 140 is not limited thereto.

The direction pattern 150 is a pattern formed in the non-transfer region 110B to distinguish a direction of the donor substrate 100. For example, when the donor substrate 100 is put into process equipment, if the donor substrate 100 is put in the opposite direction, the LEDs may be transferred to a position which is different from designed position or a defect may occur. Accordingly, the direction pattern 150 may be disposed in any one of the non-transfer regions 110B in order to distinguish a direction of the donor substrate 100. The direction pattern 150 may be formed by a printing method, a laser engraving method, or the like. For example, the direction pattern 150 may be formed of characters or figures in addition to a linear pattern illustrated in FIG. 1. In addition, the direction pattern 150 may be formed by a method of chamfering an edge of the substrate 110 in addition to a printing method or a laser engraving method, but is not limited thereto.

The resin layer 130 is disposed on one surface of the substrate 110. The resin layer 130 disposed on the transfer region 110A of the substrate 110 may support the plurality of first protrusions 131 to which the plurality of LEDs are attached during the transfer process. The resin layer 130 may be formed of a polymer resin having viscoelasticity, for example, the resin layer 130 may be composed of polydimethylsiloxane (PDMS), polyurethane acrylate (PUA), polyethylene glycol (PEG), polymethyl methacrylate (PMMA), poly styrene (PS), epoxy resin, urethane resin, acrylic resin or the like, but is not limited thereto.

The resin layer 130 includes an active region 130A and a dam region 130B.

The active region 130A is a region in which the plurality of first protrusions 131 are disposed. The active region 130A is a region in which the plurality of first protrusions 131 to which the plurality of LEDs are attached are disposed, and may be disposed to overlap at least a portion of the wafer or the display panel during the transfer process.

The dam region 130B is a region in which the plurality of second protrusions 132 are disposed. The dam region 130B is a region in which the plurality of second protrusions 132 for reducing deformation of the donor substrate 100 are disposed, and may be disposed to surround the active region 130A.

The plurality of first protrusions 131 are disposed in the active region 130A of the resin layer 130. The plurality of first protrusions 131 are protrusions on which the plurality of LEDs are disposed, and may be formed to extend from one surface of the resin layer 130. The plurality of first protrusions 131 may be formed integrally with the resin layer 130, and may be formed of a polymer material having viscoelasticity in the same manner as the resin layer 130. For example, the plurality of first protrusions 131 may be formed of polydimethylsiloxane (PDMS), polyurethane acrylate (PUA), polyethylene glycol (PEG), polymethyl methacrylate (PMMA), poly styrene (PS), epoxy resin, urethane resin, acrylic resin or the like, but is not limited thereto.

The LEDs may be temporarily attached to upper surfaces of the plurality of first protrusions 131. Specifically, the plurality of LEDs formed on the wafer may be transferred to the upper surfaces of the plurality of first protrusions 131, and the plurality of LEDs may maintain a state in which they are temporarily attached to the upper surfaces of the plurality of first protrusions 131 until being transferred to the display panel.

In this case, the plurality of first protrusions 131 may be disposed to correspond to a plurality of sub-pixels of the display panel respectively. For example, when the plurality of LEDs are transferred to the display panel, the plurality of LEDs are transferred to correspond to the plurality of respective sub-pixels of the display panel. If the plurality of LEDs transferred to the donor substrate 100 are transferred at once, only in a case in which the plurality of LEDs on the donor substrate 100 are disposed to correspond to the plurality of respective sub-pixels, the plurality of LEDs which are transferred to the display panel at once may be disposed to correspond to the plurality of respective sub-pixels. However, arrangements and intervals of the plurality of first protrusions 131 may be variously changed according to design, but are not limited thereto.

The plurality of second protrusions 132 are disposed in the dam region 130B of the resin layer 130. The plurality of second protrusions 132 are protrusions on which the plurality of LEDs are not disposed and which are disposed to reduce deformation of the donor substrate 100, and may be formed to extend from one surface of the resin layer 130. The plurality of second protrusions 132 may be formed integrally with the resin layer 130, and may be formed of a polymer material having viscoelasticity in the same manner as the resin layer 130. For example, the plurality of second protrusions 132 may be formed of polydimethylsiloxane (PDMS), polyurethane acrylate (PUA), polyethylene glycol (PEG), polymethyl methacrylate (PMMA), poly styrene (PS), epoxy resin, urethane resin, acrylic resin or the like, but is not limited thereto.

The plurality of second protrusions 132 are protrusions for reducing deformation of the resin layer 130 and the plurality of first protrusions 131 from an impact applied to the donor substrate 100 during the transfer process. For example, after bonding the wafer and the donor substrate 100, when the plurality of LEDs are transferred onto the donor substrate 100, an impact may be applied to the donor substrate 100 while the plurality of LEDs move on the donor substrate 100. When an impact is applied to the donor substrate 100, positions or shapes of the resin layer 130 and the plurality of first protrusions 131 may be deformed. At this time, the plurality of second protrusions 132 which are disposed to surround the active region 130A maintain a state in which they are bonded to the wafer, and reduce deformation of the resin layer 130 and the plurality of first protrusions 131.

In FIGS. 1 to 2B, the plurality of first protrusions 131 and the plurality of second protrusions 132 are illustrated to have the same height, but heights of the plurality of first protrusions 131 and the plurality of second protrusions 132 may be different from each other. For example, the height of the plurality of first protrusions 131 may be higher than the height of the plurality of second protrusions 132, and the height of the plurality of first protrusions 131 may be lower than the height of the plurality of second protrusions 132, but they are not limited thereto.

Meanwhile, in FIGS. 1 to 2B, although the plurality of first protrusions 131 and the plurality of second protrusions 132 are illustrated as being disposed on the resin layer 130, the resin layer 130 may be omitted and only the plurality of first protrusions 131 and the plurality of second protrusions 132 may be disposed on the substrate 110 according to design, but they are not limited thereto. In addition, only the plurality of first protrusions 131 may be disposed according to design, and the plurality of second protrusions 132 may be omitted, but they are not limited thereto.

In addition, although it has been described herein that the resin layer 130, and the plurality of first protrusions 131 and the plurality of second protrusions 132 are integrally formed, the resin layer 130, and the plurality of first protrusions 131 and the plurality of second protrusions 132 may be formed separately, but they are not limited thereto.

In FIGS. 1 to 2B, the plurality of first protrusions 131 and the plurality of second protrusions 132 are illustrated as being formed of pillars having a quadrangular cross-section, but the plurality of first protrusions 131 and the plurality of second protrusions 132 may be formed of pillars having various shapes, such as a circular shape, an elliptical shape, and a polygonal shape in cross section, but they are not limited thereto. The adhesive layer 120 is disposed between the resin layer 130 and the substrate 110. The adhesive layer 120 bonds the resin layer 130 and the substrate 110 to each other. The adhesive layer 120 may be formed of a material having an adhesive property, and may be formed of, for example, optical clear adhesive (OCA), pressure sensitive adhesive (PSA), or the like, but is not limited thereto.

However, the adhesive layer 120 may be omitted depending on design. For example, the resin layer 130 may be formed by directly coating a material constituting the resin layer 130 on the substrate 110 and then curing it. In this case, since the resin layer 130 may be attached to the substrate 110 even if the adhesive layer 120 is not disposed, the adhesive layer 120 may be omitted depending on design, but is not limited thereto.

The alignment marks 160 are formed on a surface opposite to the one surface of the substrate 110. The alignment marks 160 are components for aligning and parallelizing the donor substrate 100 with the wafer or the display panel. The alignment marks 160 may be formed by printing a colored material on the surface of the substrate 110 or by laser engraving, i.e., by burning the surface of the substrate 110. In addition, the alignment marks 160 may be formed by a method of disposing a material having excellent reflectivity, for example, chromium (Cr), silver (Ag), silver alloy (Ag-alloy), aluminum (Al), aluminum alloy (Al-alloy), molybdenum (Mo) or titanium (Ti), on the surface opposite to the one surface of the substrate 110, but is not limited thereto.

Meanwhile, the alignment marks 160 are illustrated as having a circular shape in FIG. 1, the alignment marks 160 may be formed to have various shapes such as a cross shape, a donut shape, and a quadrangular shape in addition to the circular shape, in consideration of a shape of alignment keys of the wafer, but are not limited thereto.

Meanwhile, the substrate 110, the adhesive layer 120, and the resin layer 130 may be formed of a material having transmittance which is at least higher than the alignment marks 160 of the donor substrate 100. When the substrate 110, the adhesive layer 120, and the resin layer 130 are formed of a material having transmittance higher than that of the alignment mark 160, the alignment marks 160 may be easily identified. If the transmittance of the alignment marks 160 are similar to that of the substrate 110, the adhesive layer 120, and the resin layer 130, it may be difficult to identify the alignment marks 160 and it may also be difficult to identify the alignment keys of the wafer. Accordingly, by forming the alignment marks 160 opaque, a contrast ratio between the alignment marks 160 and remaining components of the donor substrate 100 may be increased, and the alignment marks 160 may be easily identified.

Hereinafter, the donor substrate 100 and the LED transfer method using the same according to an exemplary embodiment of the present disclosure will be described with reference to FIGS. 3 to 6.

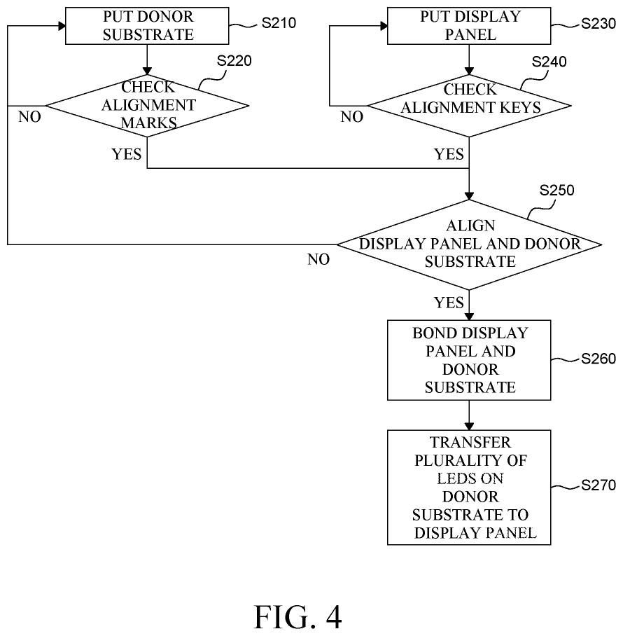

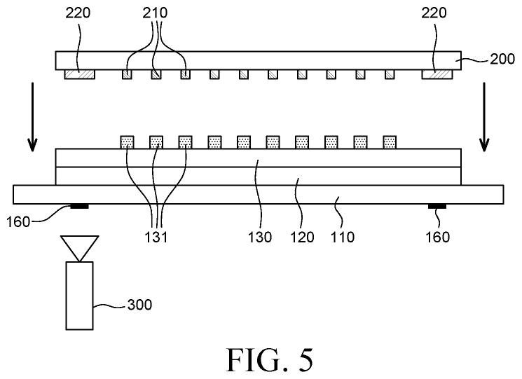

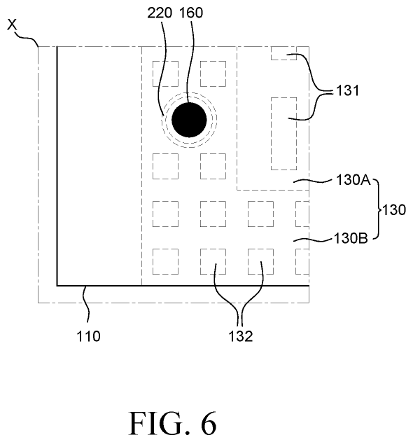

FIGS. 3 and 4 are process flowcharts for explaining the donor substrate and an LED transfer method using the donor substrate according to an exemplary embodiment of the present disclosure. FIGS. 5 and 6 are schematic process views for explaining the LED transfer method according to an exemplary embodiment of the present disclosure. Specifically, FIG. 3 is a flowchart illustrating a primary transfer process of transferring a plurality of LEDs 210 on a wafer 200 to the donor substrate 100. FIG. 4 is a flowchart illustrating a secondary transfer process of transferring the plurality of LEDs 210 on the donor substrate 100 to a display panel. FIG. 5 is a schematic cross-sectional view for explaining a process of aligning the wafer 200 and the donor substrate 100. FIG. 6 is a rear view of the donor substrate 100 with respect to region X of FIG. 1 in a state in which the wafer 200 and the donor substrate 100 are aligned.

Referring to FIG. 3, the wafer 200 on which the plurality of LEDs 210 are formed is put into process equipment in step S110.

Referring to FIG. 5 together, the wafer 200 is the substrate on which the plurality of LEDs 210 are formed. The plurality of LEDs 210 may be formed by forming a material such as GaN, InGaN or the like which constitutes the plurality of LEDs 210 on the wafer 200 to grow a crystal layer, cutting the crystal layer into individual chips, and forming electrodes thereon. The wafer 200 may be formed of sapphire, SiC, GaN, ZnO, or the like, but is not limited thereto.

In this case, on one wafer 200, the plurality of LEDs 210 emitting light of the same color may be formed, or the plurality of LEDs 210 emitting light of different colors may also be formed.

The LEDs 210 are semiconductor elements that emit light when a voltage is applied thereto. As the LEDs 210, there are LEDs 210 that emit red light, green light, blue light, and the like, and a combination of the LEDs 210 may implement to emit light of various colors including white.

The plurality of LEDs 210 may be formed in various structures such as a lateral type, a vertical type, and a flip chip type. The lateral type LED includes an n-electrode and a p-electrode which are laterally disposed on both sides of a light emitting layer. The vertical type LED includes an n-electrode and a p-electrode which are disposed above and below the light emitting layer. The flip chip type LED has substantially the same structure as the lateral type LED, and in the lateral type LED, the n-electrode and the p-electrode are laterally disposed above the light emitting layer, whereas in the flip chip type LED, the n-electrode and the p-electrode are laterally disposed below light emitting layer.

Next, alignment keys 220 on the wafer 200 which is put into process equipment are checked in step S120.

Referring to FIGS. 3 and 5 together, the alignment keys 220 are disposed on the wafer 200.

The alignment keys 220 of the wafer 200 are marks for matching alignment and a degree of parallelization with the donor substrate 100 when the plurality of LEDs 210 of the wafer 200 are transferred to the donor substrate 100. For example, by aligning the alignment keys 220 of the wafer 200 with the alignment marks 160 of the donor substrate 100, alignment and the degree of parallelization of the wafer 200 and the donor substrate 100 may be matched.

Referring back to FIG. 3, it may be checked whether the alignment keys 220 of the wafer 200 which is put into the process equipment are placed in correct positions. If the alignment keys 220 of the wafer 200 are not checked, it may return to the step of putting the wafer 200 again. If the alignment keys 220 of the wafer 200 are not placed in correct positions, they may be misaligned with the donor substrate 100 in a subsequent process. Accordingly, after checking whether the alignment keys 220 of the wafer 200 are present and whether the alignment keys 220 are in correct positions, the next process may be performed.

The donor substrate 100 is put into the process equipment in step S130. When the donor substrate 100 is put into the process equipment, the donor substrate 100 may be input based on the direction pattern 150 of the donor substrate 100.

Next, the alignment marks 160 of the donor substrate 100 put into the process equipment are checked in step S140. Specifically, as in the step S120 of checking the alignment keys 220 of the wafer 200, it may be checked whether the alignment marks 160 of the donor substrate 100 are placed in correct positions. If the alignment marks 160 of the donor substrate 100 are not checked, it may return to the step of putting the donor substrate 100 again. When the donor substrate 100 of which the alignment marks 160 are not checked is used as it is, it is difficult to match alignment and the degree of parallelization of the wafer 200 and the donor substrate 100, and defects may occur. Therefore, after checking whether the alignment marks 160 of the donor substrate 100 are present and whether the alignment marks 160 are in correct positions, the next process may be performed.

At this time, a process order of the step S110 of putting the wafer 200 and the step S120 of checking the alignment keys 220, and the step S130 of putting the donor substrate 100 and the step S140 of checking the alignment marks 160 may be performed sequentially or performed simultaneously, and the process order is not limited thereto.

Next, the wafer 200 of which the alignment keys 220 are checked and the donor substrate 100 of which the alignment marks 160 are checked are aligned in step S150.

Referring to FIGS. 3 and 5 together, in a state in which the wafer 200 and the donor substrate 100 are disposed so that the plurality of LEDs 210 on the wafer 200 and the first protrusions 131 of the donor substrate 100 face each other, alignment and the degree of parallelization of the wafer 200 and the donor substrate 100 may be matched. The wafer 200 and the donor substrate 100 may be aligned by aligning centers of the alignment keys 220 of the wafer 200 with the centers of the alignment marks 160 of the donor substrate 100. However, if it is unclear to identify the alignment keys 220 of the wafer 200 or the alignment marks 160 of the donor substrate 100, the alignment keys 220 and the alignment marks 160 may be rechecked by returning to the step S110 and S130 of putting the wafer 200 and/or the donor substrate 100 into the process equipment.

In this case, the alignment marks 160 and the alignment keys 220 may be optically inspected and aligned by disposing optical inspection equipment 300 on an outside of the donor substrate 100 and the wafer 200. For example, the alignment marks 160 of the donor substrate 100 and the alignment keys 220 of the wafer 200 may be checked by disposing the optical inspection equipment 300 such as a camera on the outside of the donor substrate 100. However, the alignment marks 160 of the donor substrate 100 and the alignment keys 220 of the wafer 200 may also be checked by disposing the optical inspection equipment 300 on the outside of the wafer 200 rather than on the outside of the donor substrate 100.

As described above, the substrate 110, the adhesive layer 120, and the resin layer 130 of the donor substrate 100 may be formed of a material having transmittance higher than the alignment marks 160, that is, a substantially transparent material. Accordingly, even if the substrate 110, the adhesive layer 120, and the resin layer 130 of the donor substrate 100 are disposed between the optical inspection equipment 300 and the alignment keys 220 of the wafer 200, since the substrate 110, the adhesive layer 120, and the resin layer 130 are substantially transparent, the alignment keys 220 of the wafer 200 may be checked even in the optical inspection equipment 300 outside the donor substrate 100.

In this case, the alignment keys 220 of the wafer 200 may be formed of an opaque material, for example, a material having excellent reflectivity to facilitate identification thereof. For example, the alignment keys 220 may be formed of a material having excellent reflectivity, such as chromium (Cr), silver (Ag), silver alloy (Ag-alloy), aluminum (Al), aluminum alloy (Al-alloy), molybdenum (Mo) or titanium (Ti), or may be a structure plated with such a material, but are not limited thereto.

Meanwhile, the alignment mark 160 and the alignment key 220 may be checked using a transmissive method or a reflective method. The transmissive method is a method of checking the alignment mark 160 on the surface opposite to one surface of the substrate 110 and the alignment key 220 of the wafer 200, which are visible through the transparent substrate 110, the adhesive layer 120, and the resin layer 130 in the optical inspection equipment 300 outside the donor substrate 100, as illustrated in FIG. 5. The reflective method is a method of further disposing a light source irradiating light toward the alignment mark 160 and/or the alignment key 220 and checking the alignment mark 160 and/or the alignment key 220 from light which is reflected from the alignment mark 160 and/or the alignment key 220. In this case, the transmissive method or the reflective method may be used according to sizes and materials of the alignment mark 160 of the donor substrate 100 and the alignment key 220 of the wafer 200. In FIG. 5, it is illustrated that the transmissive method is used for convenience of description, but is not limited thereto.

Referring to FIGS. 5 and 6, when the opaque alignment mark 160 of the donor substrate 100 is formed such that an edge inside thereof is filled, the alignment key 220 of the wafer 200 may have a size greater than the alignment mark 160 of the donor substrate 100. At least a portion of the alignment key 220 of the wafer 200 may be disposed to protrude to an outside of the alignment mark 160 of the donor substrate 100. For example, the alignment mark 160 of the donor substrate 100 may be formed in a black circular shape, and the alignment key 220 of the wafer 200 may have a diameter larger than that of the alignment mark 160 and may be formed of a circular ring shape with a hole formed in a center thereof, such as a donut so that it may be disposed to surround the alignment mark 160 of the donor substrate 100. However, the shapes of the alignment mark 160 and the alignment key 220 are not limited thereto.

If the alignment key 220 of the wafer 200 which is aligned with the alignment mark 160 of the donor substrate 100 has a size smaller than the alignment mark 160, the alignment key of the wafer 200 may be covered by the alignment mark 160 of the donor substrate 100. Accordingly, in the optical inspection equipment 300 outside the donor substrate 100, it may be difficult to check a transmission image of the alignment key 220 of the wafer 200 which is covered by the alignment mark 160. Thus, the alignment key 220 of the wafer 200 may have a size larger than the alignment mark 160 of the donor substrate 100 and may protrude to the outside of the alignment mark 160.

Then, after aligning the wafer 200 and the donor substrate 100, the wafer 200 and the donor substrate 100 are bonded in step S160, and the plurality of LEDs 210 on the wafer 200 are transferred to the donor substrate 100 in step S170.

The wafer 200 and the donor substrate 100 may be bonded so that the plurality of LEDs 210 of the wafer 200 and the plurality of first protrusions 131 of the donor substrate 100 face each other. In addition, at least a portion of the plurality of LEDs 210 of the wafer 200 may be transferred to the donor substrate 100. In this case, the transfer of the LEDs 210 from the wafer 200 to the donor substrate 100 may be performed in various manners. For example, a laser may be irradiated onto the LEDs 210 to be transferred to the donor substrate 100 among the plurality of LEDs 210, and the LEDs 210 onto which the laser has been irradiated may be detached from the wafer 200 and adhered to the plurality of first protrusions 131 of the donor substrate 100. A method of transferring the LEDs 210 from the wafer 200 to the donor substrate 100 may be variously changed according to design, but is not limited thereto.

In the primary transfer process, after aligning and bonding the donor substrate 100 and the wafer 200 using the alignment mark 160 and the alignment key 220, the plurality of LEDs 210 of the wafer 200 may be transferred to the donor substrate 100.

After the primary transfer process is completed, the secondary transfer process of transferring the plurality of LEDs 210 of the donor substrate 100 again to the substrate of the display panel may be performed, so that the display panel may be formed.

Referring to FIG. 4, the donor substrate 100 to which the plurality of LEDs 210 are adhered to the plurality of first protrusions 131 is put into process equipment in step S210, and the alignment marks 160 of the donor substrate 100 are checked in step S220.

Even in the secondary transfer process of transferring the plurality of LEDs 210 from the donor substrate 100 to the display panel, whether the alignment marks 160 of the donor substrate 100 which are put into the process equipment are in correct positions can be checked once more again. In the first transfer process of transferring the plurality of LEDs 210 from the wafer 200 to the donor substrate 100 or in a process of transporting the donor substrate 100, it is possible to check whether the alignment marks 160 are lost and whether the alignment marks 160 are placed in correct positions.

Next, the display panel is put into the process equipment in step S230, and the alignment keys of the display panel are checked in step S240.

In the display panel, display elements and a circuit, lines, and components for driving the display elements are disposed, so that the display panel may display an image. In this case, the display elements are the plurality of LEDs 210, and the plurality of LEDs 210 may be disposed in the plurality of sub-pixels and display an image.

A driving circuit including a thin film transistor, a storage capacitor, a plurality of lines, a driver IC and the like may be formed on the substrate of the display panel to drive each of the plurality of LEDs 210. In this case, the display panel used in the secondary transfer process may be a substrate in which at least a portion of the driving circuit is formed, but is not limited thereto.

Whether the alignment keys of the display panel which is put into the process equipment are placed in correct positions may be checked. The alignment keys of the display panel are also marks for matching alignment and the degree of parallelization with the donor substrate 100. After checking whether the align keys of the display panel are present and whether the align keys are in correct positions, the next process may be performed.

Next, the donor substrate 100 of which the alignment marks 160 are checked and the display panel of which the alignment keys are checked are aligned in step S250.

Alignment and a degree of parallelization of the donor substrate 100 and the display panel may be matched in a state in which the donor substrate 100 and the display panel are disposed such that the display panel and the plurality of LEDs 210 on the donor substrate 100 face each other. The donor substrate 100 and the display panel may be aligned by aligning the alignment marks 160 of the donor substrate 100 with the alignment keys of the display panel. However, if it is difficult to identify the alignment mark 160 of the donor substrate or difficult to perform alignment, the process may return to the step of putting the donor substrate 100 again into the process equipment.

At this time, as in the case of the donor substrate 100 and the wafer 200, the alignment mark 160 and the alignment key may be optically inspected and aligned from the outside of the donor substrate 100. The alignment mark 160 of the donor substrate 100 and the alignment key of the display panel may be checked by disposing the optical inspection equipment 300 disposed outside the donor substrate 100, for example, a camera.

Meanwhile, when aligning the donor substrate 100 and the display panel, the alignment keys for secondary transfer which are transferred from the wafer 200 together with the plurality of LEDs 210 instead of the alignment marks 160 of the donor substrate 100 may be used. The alignment keys for secondary transfer are transferred onto the donor substrate 100 together with the plurality of LEDs 210, and may be used to align the donor substrate 100 and the display panel. However, the donor substrate 100 and the display panel may be aligned by using the alignment marks 160 of the donor substrate 100 instead of the alignment keys for secondary transfer, and an alignment method of the donor substrate 100 and the display panel is not limited thereto.

After aligning the donor substrate 100 and the display panel, the donor substrate 100 and the display panel are bonded in step S260, and the plurality of LEDs 210 on the donor substrate 100 are transferred to the display panel in step S270.

The donor substrate 100 and the display panel may be bonded so that the plurality of LEDs 210 of the donor substrate 100 and the display panel face each other. In addition, the plurality of LEDs 210 may be transferred to correspond to the plurality of respective sub-pixels. As described above with reference to FIGS. 1 to 2B, the plurality of first protrusions 131 to which the plurality of LEDs 210 are adhered may be disposed to correspond to the plurality of respective sub-pixels. Accordingly, at least a portion of the plurality of LEDs 210 on one donor substrate 100 may be transferred onto the display panel at once. Accordingly, by completing the transfer of the plurality of LEDs 210 from the donor substrate 100 to the substrate of the display panel, the display panel may be formed.

Conventionally, alignment protrusions are formed on a resin layer having viscoelasticity to align a donor substrate and a wafer or a donor substrate and a display panel. In this case, the alignment protrusions may be formed of the same material as the resin layer in a similar manner to the plurality of first protrusions and the plurality of second protrusions and thus, be integrally formed therewith. Therefore, the alignment protrusions may be formed of a material having high transmittance, that is, may be formed substantially transparent. In addition, due to characteristics of a polymer material having viscoelasticity constituting the alignment protrusions, the alignment protrusions may be formed to have a rounded upper surface, and thus edges of the alignment protrusions may be unclearly formed. In addition, the alignment protrusions may be easily deformed or damaged by an external impact during a transport or processing process of the donor substrate. Therefore, edges of alignment protrusions of a conventional donor substrate are unclear or may be easily deformed or damaged, so that positions thereof may be changed, thereby causing defects in which a process time for identification of the alignment protrusion increases or an alignment error occurs.

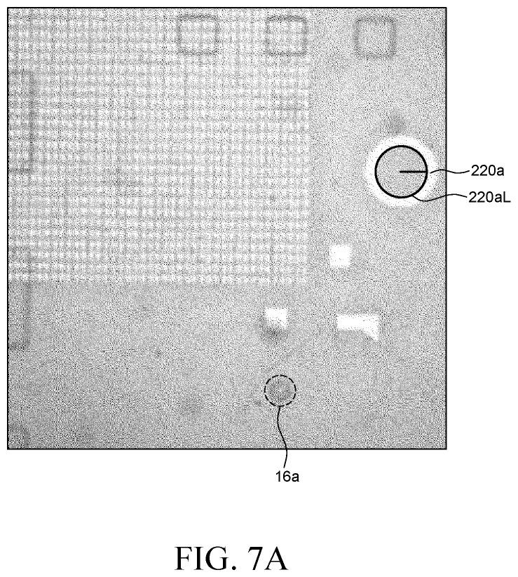

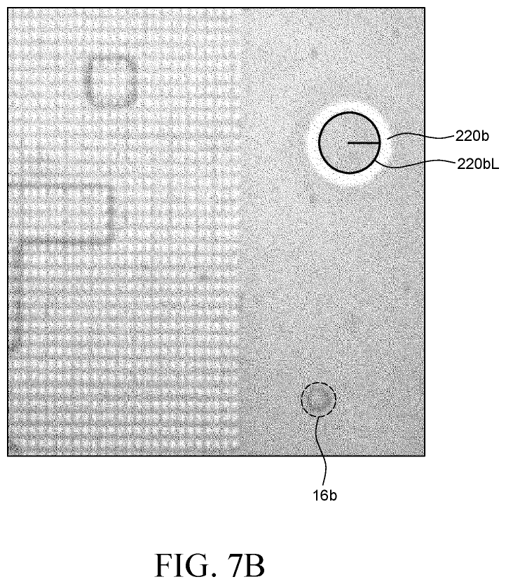

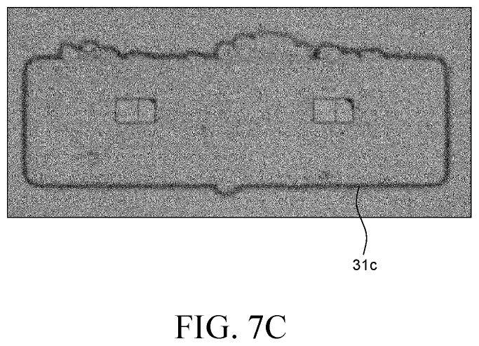

Hereinafter, a conventional alignment protrusion will be described in more detail with reference to FIGS. 7A to 7C.

FIGS. 7A to 7C are enlarged plan views of a donor substrate according to a comparative example. FIGS. 7A and 7B are images during a process of aligning a donor substrate and a wafer. FIG. 7C is an image of chip protrusions of the donor substrate. Compared to the donor substrate according to an exemplary embodiment of the present disclosure, the donor substrate according to the comparative example of FIGS. 7A to 7C has a structure in which an alignment protrusion protruding from a resin layer is disposed, instead of forming an alignment mark on an opposite surface of one surface of a substrate.

Referring to FIGS. 7A and 7B, when aligning the donor substrate and the wafer, alignment keys 220a and 220b of the wafer and an alignment protrusion 16a and 16b of the donor substrate are identified, and based on this, the wafer and the donor substrate can be aligned.

In the case of the alignment keys 220a and 220b of the wafer, they are formed of a metallic material having excellent reflectivity, so that edges thereof may be clearly visible. Accordingly, the optical inspection equipment 300 can easily identify the alignment keys 220a and 220b of the wafer, and as illustrated in FIGS. 7A and 7B, indication lines 220aL and 220bL may be marked along the edges of the alignment keys 220a and 220b of the wafer.

Meanwhile, in the case of the alignment protrusions 16a and 16b of the donor substrate, edges thereof are somewhat unclear and may be easily confused with surrounding stains. In addition, when an external force is applied to the resin layer of the donor substrate and the alignment protrusions 16a and 16b, such as a case in which the donor substrate and the wafer are bonded, the resin layer is stretched, and positions of the alignment protrusions 16a and 16b may also be deformed or the alignment protrusions 16a and 16b may be damaged. Therefore, it is difficult to identify the alignment protrusions 16a and 16b in the optical inspection equipment 300 due to unclear edges of the alignment protrusions 16a and 16b, positional deformation of the alignment protrusions 16a and 16b, and damage thereof.

For example, as illustrated in FIGS. 7A and 7B, the optical inspection equipment 300 fails to identify the alignment protrusions 16a and 16b, so that it can be confirmed that the indication lines along the edges of the alignment protrusions 16a and 16b are not marked.

Referring to FIG. 7C, a plurality of chip protrusions 31c protruding from the resin layer are disposed on the donor substrate so that a plurality of LEDs together with the alignment protrusions 16a and 16b are temporarily adhered. The chip protrusions 31c of the donor substrate according to the comparative example have substantially the same configuration as the first protrusions 131 of the donor substrate 100 according to an exemplary embodiment of the present disclosure. At this time, some of the plurality of chip protrusions 31c may be damaged due to an external impact applied as the donor substrate is repeatedly used, and it can be seen that edges thereof are deformed as illustrated in FIG. 7C. Also, the alignment protrusions 16a and 16b protruding from the resin layer may be partially damaged and deformed due to an external impact like the chip protrusions 31c. Accordingly, when the alignment protrusions 16a and 16b are damaged, it may be difficult to recognize the alignment protrusions 16a and 16b in the optical inspection equipment 300.

Accordingly, in the donor substrate 100 according to an exemplary embodiment of the present disclosure, the alignment marks 160 are formed directly on the substrate 110, so that deformation of the alignment marks 160 due to stretching of the resin layer 130 or an external impact can be reduced. Conventionally, alignment protrusions 16a and 16b formed of the same material as the resin layer are formed on the resin layer to thereby align the donor substrate and the wafer or the donor substrate and the display panel. However, since the resin layer is formed of a polymer material having viscoelasticity, when an external force is applied to the resin layer, as in a bonding process of the donor substrate and the wafer, the resin layer may be pressed and stretched. As the resin layer is stretched, positions of the alignment protrusions 16a and 16b are also changed, so that alignment accuracy of the donor substrate may be lowered. In addition, when the alignment protrusions 16a and 16b are formed of a polymer material such as a resin layer, the alignment protrusions 16a and 16b may be easily deformed or damaged by an external force or the like. Meanwhile, in the donor substrate 100 according to an exemplary embodiment of the present disclosure, since the alignment marks 160 are directly formed on the substrate 110 rather than on the resin layer 130, the positions of the alignment marks 160 may not be changed even if the resin layer 130 is stretched. And, since the alignment marks 160 are formed by a printing method, a laser engraving method, or a method of forming a metallic material having excellent reflectivity on the surface of the substrate 110, they are less likely to be deformed or damaged, as compared to the alignment protrusions 16a and 16b formed of a conventional polymer material. Therefore, in the donor substrate 100 according to an exemplary embodiment of the present disclosure, by forming the alignment marks 160 on the substrate 110 instead of the resin layer 130, deformation of the alignment marks 160 due to stretching of the resin layer 130 can be reduced, and a degree of alignment precision can be improved.

In the donor substrate 100 according to an exemplary embodiment of the present disclosure, by forming the alignment marks 160 having low transmittance on the surface of the substrate 110 instead of the resin layer 130, a contrast ratio between the alignment marks 160 and remaining components of the donor substrate 100 may be increased, and the alignment marks 160 may be easily identified. The donor substrate 100 includes the substrate 110, the adhesive layer 120 disposed on one surface of the substrate 110, the resin layer 130, the plurality of first protrusions 131 and the plurality of second protrusions 132, and the alignment marks 160 formed on a surface opposite to one surface of the substrate 110. In this case, the alignment marks 160 may be configured to have transmittance lower than that of the substrate 110, the adhesive layer 120, and the resin layer 130. For example, when forming the alignment mark 160 by a printing method, the alignment mark 160 may be formed by printing black ink. Meanwhile, the substrate 110, the adhesive layer 120, and the resin layer 130 may be formed of a material having transmittance higher than the alignment mark 160, that is, a substantially transparent material. Therefore, the contrast ratio between the alignment mark 160 and the remaining components of the donor substrate 100 can be improved. Accordingly, during the primary transfer process or the secondary transfer process, the alignment mark 160 of the donor substrate 100 can be easily identified, and a case in which the alignment mark 160 of the donor substrate 100 is not identified may be reduced. In the case in which the alignment mark 160 of the donor substrate 100 is not identified, as illustrated in FIGS. 3 and 4, it is possible to go back to the step of putting the donor substrate 100 into the process equipment, a process time may be increased. In addition, as a pre-process is delayed, a post-process may also be continuously delayed, and a time allocated to each process may also be non-uniform, unlike those designed. Accordingly, in the donor substrate 100 according to an exemplary embodiment of the present disclosure, by forming the alignment marks 160 having transmittance different from those of the remaining components of the donor substrate 100, an identification rate of the alignment marks 160 may be increased and delay in the process time can also be reduced.

In the donor substrate 100 according to an exemplary embodiment of the present disclosure, since the alignment mark 160 is formed on the opposite surface of the one surface of the substrate 110, a degree of freedom in a manufacturing method and process of the alignment mark 160 is high. Specifically, the adhesive layer 120 and the resin layer 130 are disposed on one surface of the substrate 110, and the opposite surface of the one surface of the substrate 110 is exposed to the outside. In addition, since the alignment mark 160 is formed on the opposite surface of the one surface of the substrate 110, on which components interrupting formation of the alignment mark 160 are not disposed due to the exposure thereof to the outside, the degree of freedom in a manufacturing method and process of the alignment mark 160 may be high. For example, when the alignment mark 160 is additionally formed on the donor substrate 100 which is used previously, there is no need to perform working such as separating the donor substrate 100 and the like, and the alignment mark 160 can be easily formed only by performing printing on the donor substrate 100, irradiating a laser or the like or coating a material having excellent reflectivity. Accordingly, in the donor substrate 100 according to an exemplary embodiment of the present disclosure, since the alignment mark 160 is formed on the opposite surface of the one surface of the substrate 110 which is exposed to the outside, an obstacle to the formation of the alignment mark 160 can be reduced, and the degree of freedom in a manufacturing method and process of the alignment mark 160 may be high.

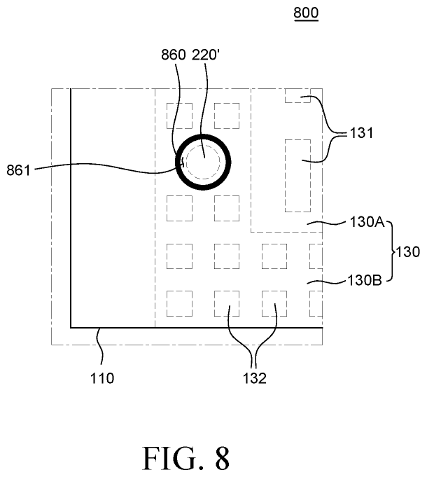

FIG. 8 is an enlarged rear view of a donor substrate according to another exemplary embodiment of the present disclosure. A donor substrate 800 of FIG. 8 is different from the donor substrate 100 of FIGS. 1 to 6 only in terms of a shape of an alignment mark 860, but other configurations thereof are substantially the same, and thus a redundant description will be omitted.

Referring to FIG. 8, the alignment mark 860 of the donor substrate 800 may include at least one hole 861 disposed inside an edge thereof. The alignment mark 860 may be formed in a form in which an inside of the edge is vacant. For example, the alignment mark 860 of the donor substrate 800 may have a circular ring shape having the hole 861 formed in a center thereof, like a donut.

When the alignment mark 860 of the donor substrate 800 includes one or more holes 861, an alignment key 220′ of the wafer 200 may be identified through the holes 861. An edge of the alignment key 220′ of the wafer 200 may be disposed inside the hole 861. For example, the alignment key 220′ of the wafer 200 may have a size smaller than the hole 861 of the alignment mark 860 and may be disposed inside the hole 861 of the alignment mark 860.

However, even when the alignment mark 860 of the donor substrate 800 includes one or more holes 861, the alignment key 220′ of the wafer 200 may have a size larger than the alignment mark 860 as illustrated in FIG. 6 and may be formed in a ring shape surrounding the alignment mark 860, but is not limited thereto.

In the donor substrate 800 according to another exemplary embodiment of the present disclosure, the shape of the alignment mark 860 may be variously configured in consideration of the alignment key 220′ of the wafer 200, the alignment key of the display panel, or an optical inspection method. The alignment mark 860 of the donor substrate 800 may be aligned with the alignment key 220′ of the wafer 200 or the alignment key of the display panel. In this case, in order to facilitate the alignment of the alignment mark 860 with the alignment key 220′ of the wafer 200 or the alignment key of the display panel, the shape of the alignment mark 860 may be variously configured. For example, when the alignment key 220′ of the wafer 200 is formed such that an inside thereof has an opaque circular shape, the alignment mark 860 of the donor substrate 800 may be formed as a circular shape having the hole 861 formed therein. In addition, the wafer 200 and the donor substrate 800 may be aligned so that the alignment key 220′ is disposed inside the hole 861. Accordingly, in the donor substrate 800 according to another exemplary embodiment of the present disclosure, by forming the alignment mark 860 in consideration of the alignment key 220′ of the wafer 200, the alignment key of the display panel, or the optical inspection method, alignment of the donor substrate 800 and the wafer 200 and the donor substrate 800 and the display panel may be facilitated.

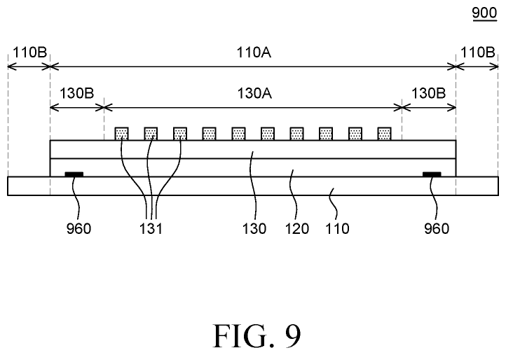

FIG. 9 is a cross-sectional view of a donor substrate according to still another exemplary embodiment of the present disclosure. A donor substrate 900 of FIG. 9 is different from the donor substrate 100 of FIGS. 1 to 6 only in terms of arrangement of alignment marks 960, but other configurations thereof are substantially the same, and thus a redundant description will be omitted.

Referring to FIG. 9, alignment marks 960 are formed on one surface of the substrate 110. The alignment marks 960 are disposed between the substrate 110 and the adhesive layer 120. The alignment marks 960 formed on one surface of the substrate 110 may be covered with the adhesive layer 120 and the resin layer 130. At this time, since the adhesive layer 120 and the resin layer 130 are formed on the one surface of the substrate 110 on which the alignment marks 960 are formed, an upper portion of the one surface of the substrate 110 may be planarized.

However, even when the adhesive layer 120 is omitted, since a material constituting the resin layer 130 is coated on the one surface of the substrate 110 on which the alignment marks 960 are formed, and then, the resin layer 130 is formed by curing it, an upper portion of the one surface of the substrate 110 may be planarized.

In the donor substrate 900 according to another exemplary embodiment of the present disclosure, by forming the alignment mark 960 on the one surface of the substrate 110 on which the resin layer 130 is to be disposed, a decrease in thickness uniformity due to the alignment mark 960 can be reduced. The alignment mark 960 may be formed by a printing method, a laser engraving method, or a method of forming a material having excellent reflectivity on one surface of the substrate 110. At this time, when the alignment mark 960 is formed by a method of irradiating a laser to the substrate 110 and performing engraving, a burr is caused in the alignment mark 960, so that one surface of the substrate 110 is not flat and can be rough. Due to such a burr, flatness of the substrate 110 may be reduced and thickness uniformity of the resin layer 130 on the one surface of the substrate 110 may be reduced, so that positions of the plurality of first protrusions 131 and the plurality of second protrusions 132 may be changed. In addition, alignment accuracy between the donor substrate 900 and the wafer 200 or the donor substrate 900 and the display panel may also decrease. Meanwhile, in the donor substrate 900 according to another exemplary embodiment of the present disclosure, the adhesive layer 120 and/or the resin layer 130 is coated and cured on the one surface of the substrate 110 on which the alignment mark 960 is formed, so that the upper portion of the substrate 110 may be planarized. Accordingly, in the donor substrate 900 according to another exemplary embodiment of the present disclosure, the adhesive layer 120 and/or the resin layer 130 is disposed to cover the alignment mark 960, so that the thickness uniformity of the resin layer 130 may be improved, and the degree of alignment precision during the transfer process may be improved, while the surface of the substrate 110 is flat.

In the donor substrate 900 according to another exemplary embodiment of the present disclosure, the adhesive layer 120 and/or the resin layer 130 may be disposed to cover the alignment mark 960, thereby reducing damage to the alignment mark 960. The donor substrate 900 on which the alignment mark 960 is formed may be repeatedly used in the primary transfer process and the secondary transfer process. That is, the first transfer process and the second transfer process may be performed by reusing the donor substrate 900. In such a processing process or transport process, the donor substrate 900 may come into contact with an external component and cause a scratch or the like. However, in the donor substrate 900 according to another exemplary embodiment of the present disclosure, since the adhesive layer 120 and/or the resin layer 130 is disposed to cover the alignment mark 960, the alignment mark 960 may not be in contact with the external component. Therefore, since the adhesive layer 120 and/or the resin layer 130 is formed to cover the alignment mark 960 in the donor substrate 900 according to another exemplary embodiment of the present disclosure, damage to the alignment mark 960 due to scratches or the like as the donor substrate 900 is repeatedly used can be reduced.

The exemplary embodiments of the present disclosure can also be described as follows:

According to an aspect of the present disclosure, there is provided a donor substrate. The donor substrate comprises a base substrate, a resin layer disposed on one surface of the base substrate, a plurality of first protrusions disposed on the resin layer, and an alignment mark disposed on the base substrate.

The alignment mark may be disposed on a surface opposite to the one surface of the base substrate.

The alignment mark may be disposed on the one surface of the base substrate.

The donor substrate may further include an adhesive layer disposed between the resin layer and the base substrate. The alignment mark may be in contact with the adhesive layer.

The resin layer may include an active region in which the plurality of first protrusions are disposed, and a dam region surrounding the active region. The donor substrate may further comprise a plurality of second protrusions disposed in the dam region.

A height of the plurality of second protrusions may be same as a height of the plurality of first protrusions.

The alignment mark may be disposed on a remaining portion except for portions overlapping the plurality of first protrusions and the plurality of second protrusions, in the one surface of the base substrate.

The base substrate may include a transfer region overlapping the resin layer, and a non-transfer region protruding to an outside of the resin layer. The donor substrate may further comprise an identification pattern disposed on the non-transfer region, and a direction pattern disposed in the non-transfer region.

The alignment mark may be disposed in the transfer region.

The base substrate and the resin layer may be formed of a transparent material, and the alignment mark may be formed of an opaque material.

According to another aspect of the present disclosure, there is a light emitting diode (LED) transfer method. The LED transfer method comprises aligning a wafer and a donor substrate, and transferring a plurality of LEDs on the wafer to the donor substrate. The donor substrate includes a base substrate on which an alignment mark is marked, a resin layer on the base substrate, and a plurality of first protrusions protruding from the resin layer. The aligning of the wafer and the donor substrate is aligning the alignment mark of the donor substrate with an alignment key of the wafer.

The alignment mark may be disposed to overlap the resin layer on a surface in contact with the resin layer among a plurality of surfaces of the base substrate.

The alignment mark may be disposed to overlap the resin layer on a surface opposite to a surface in contact with the resin layer among a plurality of surfaces of the base substrate.

The base substrate and the resin layer may be formed of a material having transmittance higher than that of the alignment mark. The aligning of the wafer and the donor substrate may be optically inspecting the alignment mark and the alignment key outside the donor substrate or outside the wafer.

An edge of the alignment mark may overlap an inside of the alignment key.

The alignment mark may include at least one hole, and an edge of the alignment key may overlap an inside of the at least one hole.

The transferring of the plurality of LEDs to the donor substrate may include transferring the plurality of LEDs onto upper surfaces of the plurality of first protrusions.

The donor substrate may further include a plurality of second protrusions protruding from the resin layer. In the transferring of the plurality of LEDs to the donor substrate, the plurality of LEDs may be spaced apart from the plurality of second protrusions.

The LED transfer method may further include aligning the donor substrate to which the plurality of LEDs are transferred, and a display panel, and transferring the plurality of LEDs which are transferred to the donor substrate, to the display panel. The aligning of the donor substrate and the display panel includes aligning the alignment mark of the donor substrate with an alignment key of the display panel.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

1. A donor substrate comprising:
a base substrate;
a resin layer disposed on one surface of the base substrate;
a plurality of first protrusions disposed on the resin layer; and
an alignment mark disposed on the base substrate.

2. The donor substrate of claim 1, wherein the alignment mark is disposed on a surface opposite to the one surface of the base substrate.

3. The donor substrate of claim 1, wherein the alignment mark is disposed on the one surface of the base substrate.

4. The donor substrate of claim 3, further comprising:
an adhesive layer disposed between the resin layer and the base substrate,
wherein the alignment mark is in contact with the adhesive layer.

5. The donor substrate of claim 1, wherein the resin layer includes:
an active region in which the plurality of first protrusions are disposed; and
a dam region surrounding the active region,
wherein the donor substrate further comprises a plurality of second protrusions disposed in the dam region.

6. The donor substrate of claim 5, wherein a height of the plurality of second protrusions is same as a height of the plurality of first protrusions.

7. The donor substrate of claim 6, wherein the alignment mark is disposed on a remaining portion except for portions overlapping the plurality of first protrusions and the plurality of second protrusions, in the one surface of the base substrate.

8. The donor substrate of claim 1, wherein the base substrate includes:
a transfer region overlapping the resin layer; and
a non-transfer region protruding to an outside of the resin layer,
wherein the donor substrate further comprises:
an identification pattern disposed on the non-transfer region; and
a direction pattern disposed in the non-transfer region.

9. The donor substrate of claim 8, wherein the alignment mark is disposed in the transfer region.

10. The donor substrate of claim 1, wherein the base substrate and the resin layer are formed of a transparent material, and
wherein the alignment mark is formed of an opaque material.

11. A light emitting diode (LED) transfer method comprising:
aligning a wafer and a donor substrate; and
transferring a plurality of LEDs on the wafer to the donor substrate,
wherein the donor substrate includes:
a base substrate on which an alignment mark is marked;
a resin layer on the base substrate; and
a plurality of first protrusions protruding from the resin layer, and
wherein the aligning of the wafer and the donor substrate is aligning the alignment mark of the donor substrate with an alignment key of the wafer.

12. The LED transfer method of claim 11, wherein the alignment mark is disposed to overlap the resin layer on a surface in contact with the resin layer among a plurality of surfaces of the base substrate.

13. The LED transfer method of claim 11, wherein the alignment mark is disposed to overlap the resin layer on a surface opposite to a surface in contact with the resin layer among a plurality of surfaces of the base substrate.

14. The LED transfer method of claim 11, wherein the base substrate and the resin layer are formed of a material having transmittance higher than that of the alignment mark, and
wherein the aligning of the wafer and the donor substrate is optically inspecting the alignment mark and the alignment key outside the donor substrate or outside the wafer.

15. The LED transfer method of claim 14, wherein an edge of the alignment mark overlaps an inside of the alignment key.

16. The LED transfer method of claim 14, wherein the alignment mark includes at least one hole, and
wherein an edge of the alignment key overlaps an inside of the at least one hole.

17. The LED transfer method of claim 11, wherein the transferring of the plurality of LEDs to the donor substrate includes transferring the plurality of LEDs onto upper surfaces of the plurality of first protrusions.

18. The LED transfer method of claim 17, wherein the donor substrate further includes:
a plurality of second protrusions protruding from the resin layer, and
wherein in the transferring of the plurality of LEDs to the donor substrate, the plurality of LEDs are spaced apart from the plurality of second protrusions.

19. The LED transfer method of claim 11, further comprising:
aligning the donor substrate to which the plurality of LEDs are transferred, and a display panel; and
transferring the plurality of LEDs which are transferred to the donor substrate, to the display panel,
wherein the aligning of the donor substrate and the display panel includes aligning the alignment mark of the donor substrate with an alignment key of the display panel.
